(19) United States
(12) Patent Application Publication
(10) Pub. No.: US 2008/0245405 A1
(43) Pub. Date: Oct. 9, 2008

(54) Integrated Solar Cell Roofing System and Method of Manufacture

(75) Inventors: Paul L. Garvison, Frederick, MD (US); Donald B. Warfield, Woodbine, MD (US); John H. Wohlgemuth, Ijamsville, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 11/817,809

(22) PCT Filed: Mar. 8, 2006
(86) PCT No.: PCT/US06/08204

§ 371 Date: Sep. 5, 2007

Related U.S. Application Data
(60) Provisional application No. 60/661,120, filed on Mar. 11, 2005.

(51) Int. Cl. H01L 31/048; E04D 13/18; H01L 31/18

(52) U.S. Cl. 136/251; 52/173.3; 438/73

(57) ABSTRACT

An integrated solar cell roofing system comprised of strips of solar cell groups. Each strip is comprised of a length of a substrate of a flexible, waterproof material. A first layer of bonding material is laid on the substrate onto which a group of pre-wired photovoltaic (PV) cells are positioned. A second layer of bonding material is applied and an individual rigid sheet of glass is laid on the second layer over each group of PV cells. Heat and vacuum is then applied to melt the bonding materials thereby bonding the group of PV cells and the glass sheet onto the substrate to form spaced solar cell groups thereon. The strip can then be folded into a fan-fold configuration for handling.

This application claims the benefit of U.S. Provisional Patent Application 60/661,120 filed on Mar. 11, 2005.

### FIELD OF THE INVENTION

The present invention relates to an integrated solar cell roofing system and in one of its aspects relates to an integrated solar cell roofing system comprising a flexible roofing material or membrane having a plurality of rigid, solar cell circuits or groups formed integral on the surface thereof and a method of manufacturing same wherein the rigid solar cell groups are spaced from each other and electrically-interconnected so that the roofing material can be folded into a fan-fold package to thereby “stack” the rigid solar cell groups one on top of the others to aid in shipping and installation of the system.

### BACKGROUND OF THE INVENTION

In recent years, considerable advances have been made in photovoltaic cells or the like for directly converting solar energy into useful electrical energy. Typically, a plurality of these photovoltaic cells are encased between a transparent sheet (e.g. glass, plastic, etc.) and a sheet of backing material to thereby form a flat, rectangular-shaped module (sometimes also called “laminate” or “panel”) of a manageable size (e.g. 2½′×5′).

This is the type of solar module which is usually installed onto the roof of an existing structure (e.g. a house, building, or the like) to provide all or at least a portion of the electrical energy used by that structure. The roofs of existing structures, be they pitched or flat, are usually formed of a substrate (e.g. plywood decking or the like) which in turn, is covered with a water-proof roofing material (e.g. shingles, waterproof membrane, or the like) as will be understood in the art. To install the solar cell modules, supports or “stand-offs”are first affixed on top of the roofing material and then the modules are fastened to their respective supports. After the modules are in place, they are electrically wired together on site to complete the solar array on the roof.

While the use of a system of individual solar modules on existing roofs has proved successful in many environments, the actual installation of such a system can be relatively expensive and time consuming. That is, this type of typical installation requires that a plurality of supports (e.g. rails, “stand-offs”, etc.) be mounted onto the top of the roof material. In addition to the cost of the supports themselves, and the labor required to properly install them on the roof, their attachment normally requires multiple penetrations of the roofing material which, in turn, can adversely affect the water-proof integrity of the roof if not completed properly. Further, since more than one module is normally used in such solar systems, the modules must be electrically interconnected on site after the modules have been installed on the roof. As will be recognized, this can be time consuming, even for a trained technician, thereby substantially adding to the overall cost of the system.

Recently, “integrated solar roofing systems” have been proposed to address many of these installation concerns. Basically, these systems involve the mounting of a plurality of flexible solar modules onto a sheet of flexible roofing material (e.g. U.S. Pat. No. 4,860,509; U.S. Pat. No. 5,482,5691; and PCT Pub. No. WO 2004/066324 A2) wherein the roofing material serves as the primary water-proofing layer for the roof. By affixing the plurality of flexible modules onto the sheet of flexible roofing material at the time of manufacture, the modules can be electrically wired together in the factory as the system is being assembled. This provides for better quality control and saves substantial installation time in the field since several modules can be put into place as the roofing material is laid onto the roof.

Further, since both the outer surface (e.g. flexible, transparent plastic sheet or the like) of the modules, themselves, and the roofing material on which the modules are mounted are flexible, the entire integrated solar roofing system can be rolled for shipping and then unrolled for installation. This too saves time since several of electrically-interconnected modules can be installed at one time directly onto the substrate of the roof (e.g. plywood) as the system is unrolled with the flexible roofing material providing the primary water-proofing layer for the roof, itself. That is, the roofing material takes the place of shingles, sheeting, or the like normally required for the roof. If more modules are needed than are contained in a single roll of the integrated roofing system, additional rolls can be installed by overlapping the respective edges of adjacent rolls and electrically interconnecting the adjacent modules.

While such approaches save considerable time in the installation of individual solar modules on a roof, the use of a flexible outer layer for the modules, themselves, may present a problem. For example, the relatively soft, outer layer (e.g. a thin sheet of clear plastic) may become scratched or otherwise damaged when the integrated system is tightly rolled for shipment and/or unrolled for installation, or it may be abraded by traffic of debris after installation. Also, the flexible plastic outer layer may absorb moisture or become discolored or the like after prolonged use which may adversely affect the efficiency of the module. Further, the flexible plastic layer may present cleaning problems in the event it becomes stained during its operational life.

Some of these concerns of using a flexible outer surface for the modules of an integrated solar roofing systems appears to have been addressed in U.S. Pat. No. 5,482,569 where tiles of reinforced glass are laid over and affixed to the solar modules of an integrated solar roofing material after the integrated roofing material has been installed on a roof. By providing a rigid, glass outer layer for the modules, the modules are better protected against the elements during their operational life. However, unfortunately, installing the solid glass tiles after the solar modules, themselves, have been installed adds an additional step to the installation procedure thereby adding to the overall costs of the system. Further, solid glass sheets can not replace the flexible outer surface (i.e. clear plastic) of the modules in the known prior integrated solar roofing systems since to do so would eliminate the ability of the system to be rolled for shipping and installation as taught by the patents and patent application referred to above.

Accordingly, a need exists for an integrated solar cell roofing system which can utilize the benefits of a solid glass outer layer but at the same time can be packaged for easy shipment and installation.

### SUMMARY OF THE INVENTION

The present invention provides an integrated solar cell roofing system and a method of manufacturing and installing same. Basically, the system is comprised of strips of pre-wired solar circuits wherein the strips can be folded into a fan-fold configuration for shipping, handling, and installation.

More specifically, the present roofing system is comprised of strips of integrated solar cell circuits formed thereon. Each strip (e.g. six cell circuits, twelve cell circuits, etc.) is comprised of a length of a substrate comprising a flexible, waterproof material (e.g. single ply polymer, rubber membrane, etc.) which may be cut from a continuous roll of material before or after the cell circuits are formed thereon or may be otherwise provided.

In one embodiment, a first layer of bonding material (e.g. ethylene vinyl acetate and crane glass) is laid down on the substrate and groups of pre-wired photovoltaic cells (e.g. 72 PV cells) are spaced thereon. The groups of PV cells are spaced from each other to provide a sufficient gap between adjacent groups to allow the finished strip to be folded into the desired, fan-fold configuration without damaging the substrate.

The groups of PV cells are electrically-connected to each other and a second layer of bonding material (e.g. ethylene vinyl acetate) is placed over the groups of PV cells and the related wiring. Individual rigid, reinforced clear glass sheets are then positioned onto the second layer of bonding material to cover the respective groups of PV cells. A common output of the interconnected groups of PV cells is connected to a power cable or the like through a junction box positioned at the end of the strip.

The assembled components are then laminated by applying vacuum and heat thereto to remove air from the assembly and to melt and cross-link the bonding materials to thereby bond the individual, spaced solar cell circuits to the substrate; each cell circuit being formed by a group of PV cells and a respective glass cover sheet. While the cell groups may be laminated one at a time, it is preferred to laminate more than one cell group in a single operation to save both time and money.

Once a strip is completed, it can be folded into a fan-fold configuration wherein the glass sheets on the cell groups lie substantially flat with respect to each other so that all of the cell groups are stacked relatively vertically one on top of another for ease in handling, shipping, and installation. Once on site, a strip is unfolded and the flexible, waterproof substrate is attached (e.g. glued) to the roof surface (e.g. plywood decking). Since the substrate is waterproof, it can provide the primary roofing material for that area. If needed, a second strip is unfolded and its substrate is overlapped with the substrate of the first strip and/or with surrounding roofing material to prevent leakage as in keeping with good roofing procedures.

The advantages of the present integrated solar cell roofing system are many. Several solar cell circuits can be pre-wired and laminated onto a single strip of substrate which can save substantial amounts of time and money in both fabrication and installation. Further, the substrate, being formed from waterproof material, serves as the primary roofing material in the area occupied by the solar cell circuits. This greatly simplifies the installation of the solar cell circuits and reduces the amount of roofing material which would otherwise be needed in more conventional solar installations of this general type. Still further, since the substrate is flexible, a strip of solar cell circuits can be folded for shipping and handling. Additional advantages will be recognized from the following descriptions.

### BRIEF DESCRIPTION OF THE DRAWINGS

The actual construction operation, and apparent advantages of the present invention will be better understood by referring to the drawings, not necessarily to scale, in which like numerals identify like parts and in which:

FIG. 1 is a perspective view of an embodiment of the integrated solar roofing system of the present invention as installed on the roof of a typical structure;

FIG. 2 is a top view, partly broken away, of a strip of the integrated solar roofing system of FIG. 1;

FIG. 3 is a representative, cross-sectional view of the strip of integrated solar system of FIG. 2 when folded into a fan-fold package for handling; and

FIG. 4 is a cross-sectional view of the strip of the integrated solar roofing system of FIG. 2 taken along line 4-4 of FIG. 2.

While the invention is described herein in connection with its preferred embodiments, it will be understood that this invention is not limited thereto. On the contrary, the invention is intended to cover all alternatives, modifications, and equivalents that may be included within the spirit and scope of the invention, as defined by the appended claims.

### DETAILED DESCRIPTION OF THE INVENTION

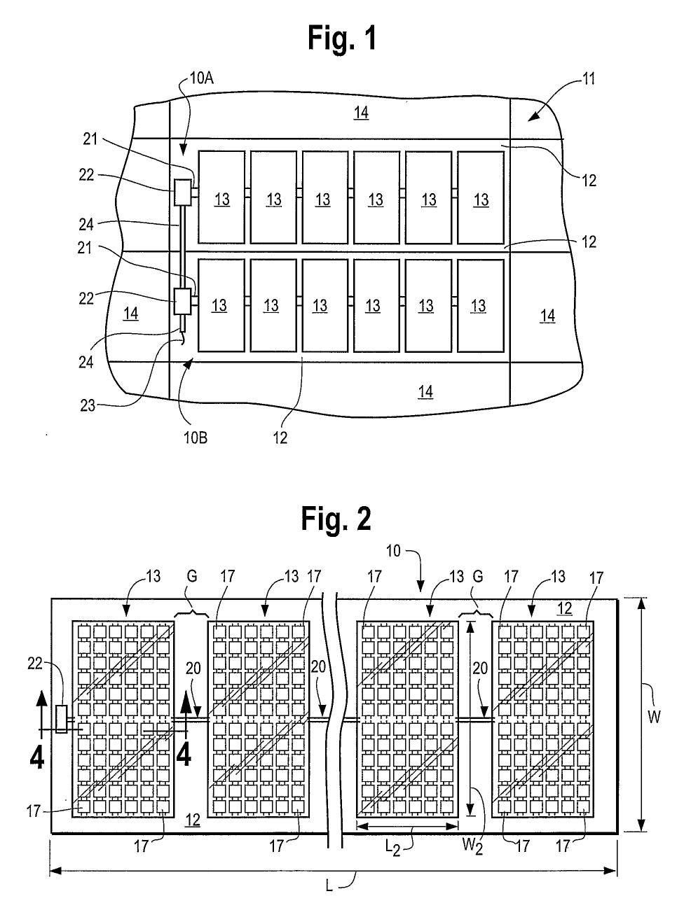

Referring now to the drawings, FIG. 1 is a top view which illustrates two strips 10A and 10B of an embodiment of the present integrated roofing system installed onto a roof 11 of a building or the like. While roof 11 is shown as a “flat roof”, it should be understood that the present invention can be used equally as well with other types of roofs, e.g. pitched. As shown in FIG. 1 and as will be further described in detail below, each strip 10 is comprised of a flexible, water-proof substrate 12 which has a plurality of rigid, glass-covered, solar cell groups 13 (only some numbered for clarity) spaced thereon.

The substrate 12 is glued or otherwise secured to the surface (e.g. plywood decking 14) of roof 11 so that the substrate lays flat on the surface with the cell groups 13 exposed to the sun. Since substrate 12 is of a waterproof material, it will provide the primary roofing material for the roof in the area lying under the strips. A more detailed description of the cell groups 13 and the installation of the strips 10 onto a roof will follow below.

To fabricate or manufacture strips 10 in accordance with an embodiment of the present invention, a length L (FIG. 2) of the desired width W of flexible, water-proof material 12 is first unrolled from a continuous roll of the material (not shown) or length L may be provided from some other source. While the actual measurements of any particular strip will depend on the actual application involved, the following dimensions are set forth as an example of a typical application to better understand the present invention.

Typical measurements of a solar cell group 13 of the type which can be used in the present invention are approximately thirty-one (31) inches across (L₂ in FIG. 2) and sixty-three (63) inches high (W₂). A gap G of, for example, at least 1 inch will be needed between adjacent cell groups 13 for a purpose described later. Since the substrate material 12 serves as the primary waterproofing membrane for roof 11, an overlap (approximately 6-7 inches) is needed at the edges of the strip as will be understood in the roofing industry. Using these dimensions, a strip having six spaced cell groups 13 thereon would have a width W of approximately 6.5 feet and a length L of approximately 17 feet. If twelve cell groups are formed on strip 10, the width would remain the same but the length would become approximately 33 feet. While most flexible, waterproof, roofing-type materials can be used for substrate 12, typical examples are a single ply polymer material (e.g. thermoplastic polyolefin (TPO) or polyvinylchloride (PVC)) or a rubber membrane (e.g. ethylene propylene diene monomer rubber (EPDM)).

Once the desired number of solar cell groups per strip is determined, the cell groups are spaced and assembled along the required length of substrate material 12, being sure to leave the desired gap G between adjacent cell groups. Since all of the modules 13 are suitably formed basically in the same manner, only one will be described in detail. Referring now to FIG. 4, a first layer 16 of bonding material is laid onto substrate 12. While this layer 16 can be restricted just to the areas corresponding to the individual solar cell groups 13, preferably layer 16 is laid continuously along the entire length of the substrate which will be occupied by all of the cell groups since the bonding material in gaps G will not present a problem and since the continuous layer technique is much easier, quicker, and less demanding in the manufacturing process.

First bonding layer 16 is preferably comprised of ethylene vinyl acetate (“EVA”) and “crane glass”. “Crane glass” as known in the industry is comprised of a very thin layer of flexible glass fibers which is used to reinforce the EVA layer. In the present invention, the crane glass also reduces the surface friction between the photovoltaic cells 17 (“PV cells”) and the EVA in bonding layer 16 so that the PV cells can be more easily repositioned on the EVA layer as may be required during assembly. Once the bonding layer 16 is in place, a group of pre-wired PV cells 17, which will form the core of a cell group 13, is placed on the bonding layer 16 in its predetermined position.

Typically, the group of PV cells is comprised of seventy-two (72), electrically interconnected PV cells 17 which are wired in a rectangular pattern (see FIG. 2). As will be understood in the art, each cell 17 has a positive and a negative lead (collectively numbered as 18 in FIG. 4) which can be electrically interconnected through respective bus bars 19 or the like to effectively form a unitary circuit having a single inlet and a single outlet. The respective outputs and inputs of adjacent groups of PV cells 17 are preferably electrically interconnected by connections 20 so that all of the solar cell groups 13 on strip 10 will effectively function as a single unit in generating the electrical power generated from strip 10 through a single output 21 (see FIG. 4).

Output 21 is routed from bus bar 19 so that it can be received into junction box 22 where it is electrically coupled to a power cable 23 (FIG. 1) as will be understood in the art. As shown in FIG. 1, the output from the junction box 22 on strip 10A is electrically connected to the output in the junction box 22 on strip 10B from which the power cable 23 transfers the power generated by integrated solar cell roofing system to a user terminal. As will be recognized, conduits 24 can be used to protect the output from the strips and power cable 23. All of the electrical connections required (a) between the individual PV cells 17, (b) between adjacent solar cell groups 13, and (c) between the strips 10 can all be made in accordance with accepted electrical interconnection techniques well known in the solar cell art.

Once the groups of PV cells 17 are properly positioned and interconnected, a second bonding layer 25 is laid over the groups of cells 17 and related wiring. This layer is similar to layer 16 but preferably is comprised only of EVA. An individual sheet of reinforced, rigid clear glass 26 having a desired size and thickness is positioned onto second bonding layer 25 so that it covers a respective group of the PV cells 17. A narrow strip 27 of protective material (e.g. tedlar/polyester) can be positioned between adjacent glass sheets 26 to provide protection between the glass sheets during assembly, shipping, and installation.

With all components so assembled, each solar cell group 13 is then laminated by placing the cell group in a “laminator” or the like where it is subjected to both vacuum and heat. Typically, the vacuum and heat is applied for a set time (e.g. 15 minutes) to remove air from the cell group and to melt and crosslink the EVA or other bonding materials in both layers 16 and 25. The EVA will melt around the crane glass in layer 16 so that the crane glass effectively disappears. The EVA will also melt around the PV cells 17 and related electrical connections thereby bonding the cells and the respective glass sheets 26 to the substrate 12 to thereby form the individual spaced solar cell groups 13.

While the solar modules 13 can be assembled and laminated one at a time, it is preferred to assemble as many cell groups onto a continuous length of substrate material 12 as can be fitted into a particular laminator so that a plurality of cell groups can be laminated during a single cycle of the laminator. In certain known laminators, at least three cell groups 13 of a typical size can be laminated onto a continuous length of substrate 12 during a fifteen (15) minute cycle. Therefore, a strip 10 having twelve solar cell groups 13 thereon could be completed in approximately one hour. Before or after lamination, the length of substrate material 12 of the finished strip 10 can then be cut off the continuous roll and junction box 22 attached to complete the assembly.

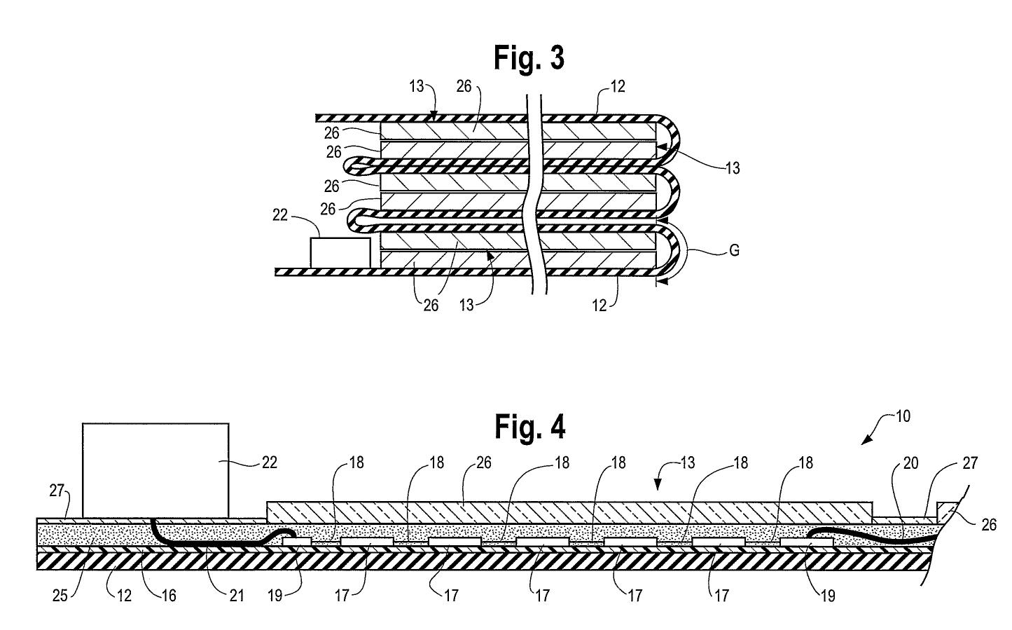

Once the manufacture of a strip 10 is complete, it can be folded into a “fan-fold” configuration for handling, shipping, and installation. Substrate 12, being comprised of a flexible material, can easily be folded without being damaged or adversely affecting its waterproofing capabilities. As best seen in FIG. 3, the substrate 12 is folded back upon itself so that the cell group 13 will lie substantially flat with respect to each other and will be stacked relatively vertically, one on top of another.

As set out above, a sufficient gap G is provided between the cell groups 13 to allow for the adequate folding of strip 10 into the desired fan-fold configuration and to allow the modules to lie relatively flat with respect to each other. Of course, any adequate packing material (not shown) can be removably placed between the glass sheets 26 of directly contacting modules 13 to protect the glass surfaces during shipping and handling.

Strips 10 of the integrated solar roofing system will preferably be shipped to their destinations in the fan-fold configuration described above. Once there, each strip 10 will be unfolded onto the surface (e.g. plywood decking) of the roof and the substrate 12 will be glued or otherwise secured thereto. Since substrate 12 of strip 10 is, itself, a waterproof, roofing material, no other roofing material will be needed in the areas covered by substrate 12. Of course, strips 10 (e.g. 10A, FIG. 1) will be overlapped with other strips (e.g. 10B) and/or with any other surrounding roofing materials to provide a water-tight roof in accordance with accepted roofing practices. Since all of the PV cells 17 in a group have been pre-wired and all of the cell groups 13 on a strip have been electrically connected at the factory, only the electrical connections between strips 10 and to the final terminal need to be made on site thereby saving substantial time in installing the system.

Although the invention has been described as using a preferred glass sheet 26 to cover the solar cells, it is to be understood that such sheet can be made of other materials instead of or in addition to glass. Thus, any suitable material that is preferably, rigid, scratch resistant, waterproof, UV resistant and weatherproof can be used for such sheet. One or more sheets made of glass or such other materials, in any suitable combination, can be used. EVA is described herein as being the preferred bonding material; however, other materials that are suitable for the bonding of the solar cells to the substrate or to the sheet 26 can be used. Other suitable bonding materials include, for example, a urethane or silicone.

U.S. Provisional Patent Application 60/661,120 filed on Mar. 11, 2005, is incorporated herein by reference in its entirety.

What is claimed is:

1. A strip of an integrated solar cell roofing system comprising:
a substrate comprising a length of flexible, waterproof material;
a plurality of rigid solar cell groups formed on said substrate, said plurality of rigid solar cell groups spaced from each other along said length of said substrate to provide a gap between adjacent said solar cell groups, said gap being sufficient to allow said length of substrate to be folded into a fan-fold configuration wherein said plurality of solar cell groups lie substantially flat with respect to each other and are stacked relatively vertical one on top of another.

2. The strip of an integrated solar cell roofing system of claim 1 wherein each of said plurality of solar cell groups comprises:
a layer of bonding material on said substrate;
a group of electrically connected photovoltaic cells positioned onto said layer of bonding material; and
a sheet of rigid, clear glass positioned over said group of electrically connected photovoltaic cells.

3. The strip of an integrated solar cell roofing system of claim 2 wherein said layer of bonding material is comprised of ethylene vinyl acetate.

4. The strip of an integrated solar cell roofing system of claim 3 wherein said layer of bonding material further comprises:
crane glass.

5. The strip of an integrated solar cell roofing system of claim 4 including:
a second layer of bonding material laid over said group of said electrically connected photovoltaic cells.

6. The strip of an integrated solar cell roofing system of claim 5 wherein said length of substrate is comprised of a single ply polymer material.

7. The strip of an integrated solar cell roofing system of claim 5 wherein said length of substrate is comprised of a rubber membrane.

8. The strip of an integrated solar cell roofing system of claim 1 wherein said substrate is of a length sufficient to provide overlap with an adjacent strip when said strips are installed on a roof.

9. A method of assembling a strip of an integrated solar cell roofing system, said method comprising:
providing a length of a flexible, waterproof substrate;
laying a first layer of bonding material on said substrate;
positioning a plurality of groups of electrically-connected photovoltaic cells at spaced intervals along said length of substrate leaving a gap between adjacent said groups;
positioning an individual sheet of glass over each said group of photovoltaic cells; and
applying a vacuum and heat to said strip to thereby laminate and bond each of said groups and its respective sheet of glass onto said substrate to form individual, spaced solar cell groups along said substrate.

10. The method of claim 9 including:
placing a second layer of bonding material over said plurality of said groups of photovoltaic cells before positioning said sheets of glass over said groups.

11. The method of claim 9 wherein said first layer of bonding material is comprised of ethylene vinyl acetate and crane glass and said second layer of bonding material is comprised of ethylene vinyl acetate.

12. The method of claim 10 wherein said length of said substrate is provided from a continuous roll of substrate.

13. The method of claim 10 wherein said vacuum and heat is applied to a plurality of groups at the same time.

14. The method of claim 10 wherein said substrate is folded into a fan-fold configuration when all of said solar cell groups have been formed thereon so that each of said groups will lie substantially flat with respect to each other and will be stacked relatively vertical one on top another.

15. A method of installing of an integrated solar cell roofing system which is comprised of strips of solar cell groups wherein each of said strips, in turn, is comprised of a length of a flexible, waterproof substrate having a plurality of rigid, glass covered, solar cell groups formed integral thereon, said cell groups being spaced from each other so that said length of said substrate can be folded for shipping and handling into a fan-fold configuration wherein said cell groups lie substantially flat one on top another, said method comprising:
unfolding a first said strip on a roof structure so that said substrate lies substantially flat on said roof surface and all of said solar cell groups are exposed toward the sun; and
attaching said substrate to said roof wherein said substrate provides the primary waterproofing for the roof support which lies under said strip.

16. The installation method of claim 15 including:
unfolding a second strip of said integrated solar cell roofing system on said roof so that the substrate of said second strip overlaps said substrate of said first strip; and
attaching said second substrate to said roof.

17. The installation method of claim 16 including:
electrically-connecting the solar cell groups on said first and second strips.
